(19) United States
(12) Patent Application Publication
(10) Pub. No.: US 2011/0155245 A1
(43) Pub. Date: Jun. 30, 2011

(54) SOLAR MODULE HAVING A SIDE INSULATING MEMBER

(75) Inventors: Wei-Lun Hsiao, Taoyuan City (TW); Hsiang-Yi Yu, Taoyuan City (TW); Hsuan-Ping Chen, Qiaotou Township (TW)

(73) Assignee: Du Pont Apollo Limited, Pak Shek Kok, N.T. (HK)

(21) Appl. No.: 12/978,531

(22) Filed: Dec. 24, 2010

Related U.S. Application Data
(60) Provisional application No. 61/291,428, filed on Dec. 31, 2009.

(51) Int. Cl. H01L 31/02

(52) U.S. Cl. 136/261; 136/252

(57) ABSTRACT

Disclosed herein is a solar module, which includes a solar cell unit and an insulating member. The insulating member covers at least one side of the solar cell unit in thickness direction so as to extend the creepage distance along the thickness direction of the solar cell unit and is at least 8.4 mm.

### RELATED APPLICATIONS

This application claims priority to U.S. Provisional Application Ser. No. 61/291,428, filed Dec. 31, 2009, which is herein incorporated by reference.

### BACKGROUND

1. Field of Invention

The present invention relates to a photovoltaic device. More particularly, the present invention relates to a solar cell module having a non-linear creepage length.

2. Description of Related Art

Solar energy has gained many research attentions for being a seemingly inexhaustible energy source. For such purpose, solar modules that convert solar energy directly into electrical energy are developed.

FIG. 1 is a cross-sectional view illustrating a solar module 10 in the prior art. Typically, solar module 10 includes a first substrate 11, a second substrate 12, a photovoltaic layer 13, and a sealing layer 14. The photovoltaic layer 13 is capable of converting light into electricity, and is formed on the second substrate 12. The sealing layer 14 such as a layer of ethylene-vinyl acetate coploymer (EVA) is used to encapsulate the first and second substrates 11, 12 together.

In general, an electrical leakage path 15 occures in the solar module 10, as depicted in FIG. 1. The leakage path 15 starts from the edge of the photovaltaic layer 13, along the surface of the second substrate 13, and ends at the edge of the second substrate 12. The distance of the leakage path is also known as creepage distance. According to the requirement of the International standard IEC 61730-1, the creepage distance of a solar module 10 at least requires 8.4 mm while the maximum system operating voltage is in the range of 601-1000 V, class A. Therefore, in the prior art, an absent region with a distance al of at least 8.4 mm is purposed to be leaved for fulfilling the requirement. As a result, the solar module 10 has an ineffective area surrounding the photovoltaic layer 13, and thus decreases the ratio of an effective area in the solar modular 10. Therefore, there exists in this art a need of an improved solar module, which would have a decreased ineffective area and fulfill the requirement of IEC 61730-1.

### SUMMARY

The present disclosure provides a solar module, which includes a solar cell unit and an insulating member. The insulating member covers at least one side of the solar cell unit in a thickness direction so as to extend the creepage distance along the thickness direction of the solar cell unit and is at least 8.4 mm. The solar cell unit includes a first substrate, a second substrate and a photovoltaic member. The second substrate is substantially aligned with the first substrate, and the photovoltaic member is disposed between the first and second substrates.

In one embodiment of the present disclosure, the insulating member has a thickness of about 0.1 mm to about 1 mm, and comprises a polymer layer, a metal layer and an insulating layer, with the metal layer being positioned between the insulating layer and the polymer layer.

In another embodiment of the present disclosure, the insulating member has a substantially U-shaped cross section.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view illustrating a solar module in the prior art;

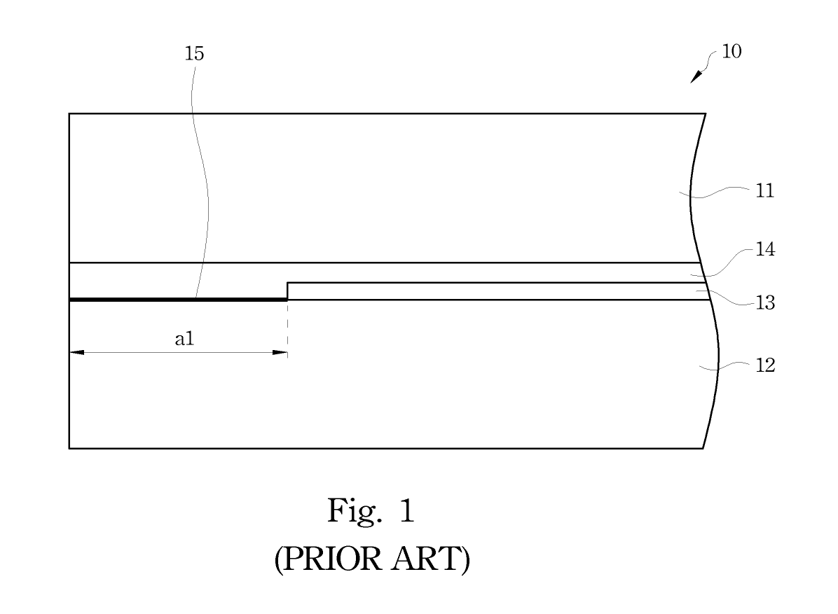

FIG. 2 is a cross-sectional view of a solar module according to one embodiment of the present disclosure;

FIG. 3 is a cross-sectional view of a solar module according to another embodiment of the present disclosure; and

FIG. 4 is a cross-sectional view of a solar module according to still another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

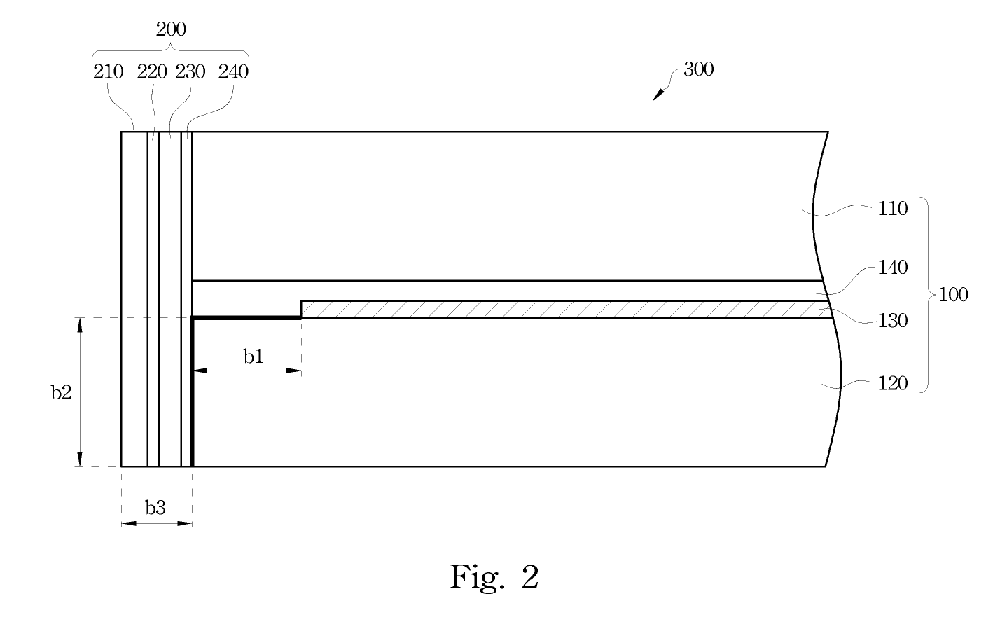

FIG. 2 is a cross-sectional view of a solar module 300 according to one embodiment of the present disclosure. As depicted in FIG. 2, the solar module 300 includes a solar cell unit 100 and an insulating member 200. The solar cell unit 100 is capable of converting light into electricity, and comprises a first substrate 110, a second substrate 120 and a photovoltaic member 130. The insulating member 200, which comprises an insulating layer 230, covers at least one side of the solar cell unit 100 in thickness direction. Moreover, the insulating member 200 is capable of providing excellent electrical insulation, weather resistance, UV resistance and moisture barrier properties.

The creepage distance of the solar module 300 may be defined according to the leakage path along the surface of the insulating material. In general, the creepage distance of the solar module 300 is associated with the position of the photovoltaic member 130 and the leakage path present in the solar module 300. When the insulating member 200 covers one side of the solar cell unit 100, the leakage path of the solar module 300 may be extended along the thickness direction of the second substrate 120. As depicted in FIG. 2, the creepage distance of the solar module 300 may be defined as the sum of the distances b1 and b2, in which b1 is the distance between the edge of the photovoltaic member 130 and the edge of the second substrate 120, and b2 substantially equals the thickness of the second substrate 120. According to the requirement of the International standard IEC 61730-1, the creepage distance (i.e., b1+b2) is at least 8.4 mm. Hence, as the distance along the side surface of the second substrate 120 in thickness direction increases, the distance between the edge of the photovoltaic member and the edge of the second substrate 120 decreases correspondingly. For example, when b2 equals 4.4 mm, b1 may have a value of 4 mm and satisfy the requirement of IEC 61730-1. Therefore, a photovoltaic member 130 having a larger surface area may be used. As a result, the effective area, which converts light into electricity, is increased compared with the prior art. In particular, when the thickness of the insulating member b3 is less than the thickness of the second substrate b2, the effective area of the entire solar module 300 still increases, for the ineffective distance, which is the sum of the b3 and b1, is still less than 8.4 mm. For example, b1, b2, b3 are respectively 4 mm, 4.4 mm and 2 mm. The ineffective distance of the solar module 300 is only 6 mm (b1+b3). In the example, the photoelectrical conversion efficiency of the entire solar modular 300 may be increased about 1% to about 3%.

In one embodiment, the insulating member 200 has a thickness of about 0.1 mm to about 1 mm. In another embodiment, the insulating member 200 may comprise, but is not limited to, a polymer layer 210, a metal layer 220 and an insulating layer 230, depending on the needs. The metal layer 220 is disposed between the insulating layer 230 and the polymer layer 210. In one example, the polymer layer 210 comprises a fluorinated polymer or polyimide polymer. The metal layer 220 may be an aluminum layer, and the insulating layer 230 may be made from polyethylene terephtalate (PET). The polymer layer 210 may provide a function of weather resistance and is usually situated at the outmost surface of the insulating member 200. The metal layer 220 such as aluminum layer may provide moisture resistance. The insulating layer 230 is used to direct the leakage path toward and along the side surface of the second substrate 120 in the thickness direction. In other examples, the insulating member 200 may further comprises an adhesive layer 240 which adjoins the insulating layer 230 and the side of the solar cell unit 100.

The solar cell unit 100 is described in detail hereinafter. As depicted in FIG. 2, the solar cell unit 100 comprises a first substrate 110, a second substrate 120 and a photovoltaic member 130. The first and second substrates 110, 120 may protect photovoltaic member 130 from damage, and may further prevent mist and pollutions from leaking into photovoltaic member 130. Moreover, the first and second substrates 110, 120 may prevent the electrical leakage of the photovoltaic member 130.

The first and second substrate 110, 120 are substantially aligned with each other, and at least one of the first and second substrates 110, 120 is transparent to sunlight for propagating sunlight to the photovoltaic member 130. The material of the first substrate 110 may be same as or different from the second substrate 120. In one embodiment, both the first and second substrates 110, 120 are made from a transparent insulating material. For example, the first and second substrate 110, 120 may be made of glass or other transparent plastics such as Poly(methyl methacrylate) (PMMA), polystyrene and polycarbonate. In another embodiment, at least one of the first and second substrates 110, 120 has a thickness of about 3.2 mm to about 12 mm.

The photovoltaic member 130 is disposed between the first and second substrates 120, and is capable of converting light into electricity. In one embodiment, the photovoltaic member 130 is formed directly on the first substrate 110 or on the second substrates 120. For example, the photovoltaic member 130 may be a thin film photovoltaic layer, which is deposited on the second substrate 120. More specifically, the photovoltaic member 130 may comprise amorphous silicon and has a p-i-n structure composed of a p-type semiconductor, an intrinsic semiconductor and an n-type semiconductor (not shown). In other embodiments, the photovoltaic member 130 may be a silicon chip comprising single crystal or polycrystalline silicon.

In one embodiment, the solar cell unit 100 further comprises a sealing layer 140. The sealing layer 140 is disposed between the first and second substrates 110, 120 and above the photovoltaic member 130. The sealing layer 140 encapsulates the first and second substrates 110, 120 together, and forms a single unit. The sealing layer 140 may be a layer of ethylene-vinyl acetate copolymer (EVA) or polyvinyl butyral (PVB), for example.

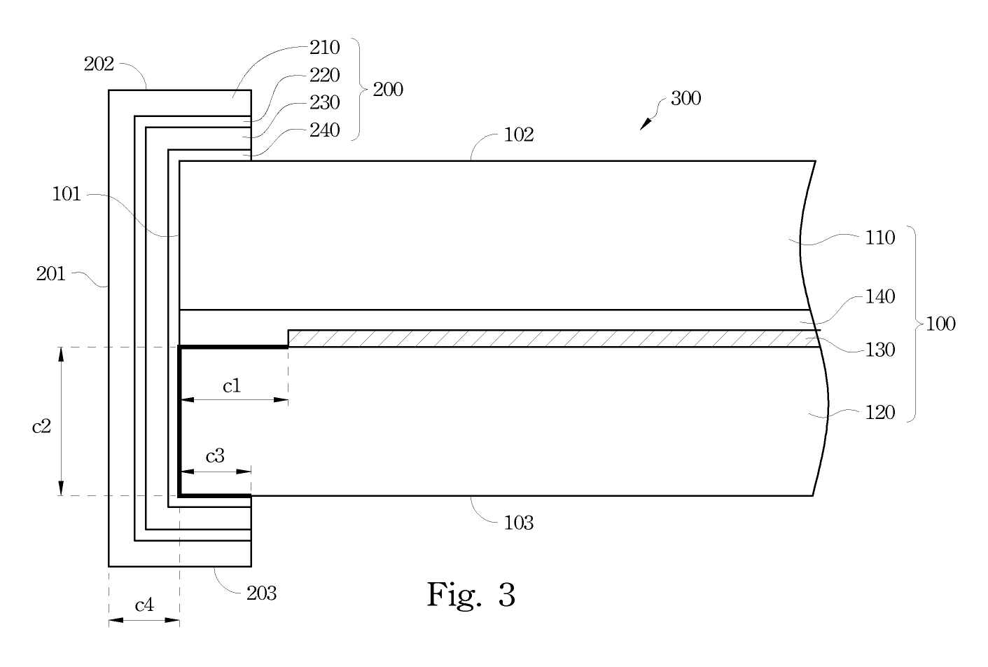

FIG. 3 is a cross-sectional view of a solar module 300 according to another embodiment of the present disclosure. As illustrated in FIG. 3, the solar module 300 includes a solar cell unit 100 and an insulating member 200. The insulating member 200 substantially has a U-shaped cross section. The insulating member 200 has a first portion 201, a second portion 202, and a third portion 203. The first portion 201 covers the side surface 101 of the solar cell unit 100. The second portion 202 covers a portion of the upper surface 102 of the solar cell unit 100, and the third portion 203 covers a portion of the lower surface 103 of the solar cell unit 100. In this embodiment, the insulating member 200 is composed of a polymer layer 210, a metal layer 220, an insulating layer 230 and an adhesive layer 240, as described in the embodiment of FIG. 2. The solar cell unit 100 may have a same structure as those described hereinbefore.

In this embodiment, the creepage distance may be defined as the sum of c1, c2, and c3, wherein c1 is the distance between the edge of the photovoltaic member 130 and the edge of the second substrate 120, and c2 is substantially equals the thickness of the second substrate 120, and c3 is the distance between the edge of the second substrate 120 and the edge of the third portion 203 of the insulating member 200, as depicted in FIG. 3. In one example, c2 (the thickness of the second substrate 120) is about 4.4 mm, and c3 is about 2 mm. Therefore, c1 may has a value of 2 mm and satisfy the requirement of IEC 61730-1. As a result, the photovoltaic member 130 may be further enlarged towards the edge of the second substrate 120 and the effective area of the solar module 300 may be further increased. In particular, the effective area of the entire solar module 300 may further be increased. For example, if c1, c2, c3, c4 are respectively 2.4 mm, 4 mm, 2 mm and 2 mm, the ineffective distance of the solar module 300 is only 4.4 mm (c1+c4).

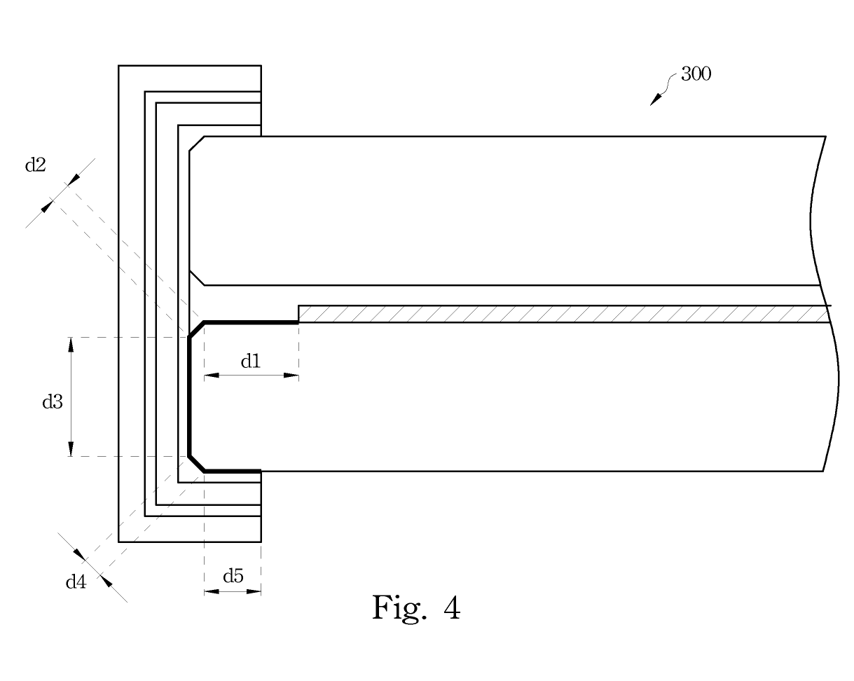

FIG. 4 is a cross-sectional view illustrating a solar module 300 according to another embodiment of the present disclosure. The structure of the solar module 300 depicted in FIG. 4 is substantially the same as the embodiment illustrated in FIG. 3, except both the first and second substrates 110, 120 have chamfers or rounding edges. In the embodiment, the creepage distance further include the lengths of the chamfers d2 and d4, that is the creepage distance is the sum of d1, d2, d3, d4 and d5, as depicted in FIG. 4. As described hereinbefore, the effective area of the entire solar module 300 may be increased compared to the prior art.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A solar cell module, comprising:
a solar cell unit, comprising,
a first substrate;
a second substrate, which is substantially aligned with the first substrate; and
a photovoltaic member disposed between the first and second substrates and defines a creepage distance of the solar cell unit; and
an insulating member covered at least one side of the solar cell unit in a thickness direction so as to extend the creepage distance along the thickness direction of the solar cell unit.

2. The solar cell module according to claim 1, wherein the insulating member has a thickness of about 0.1 mm to about 1 mm.

3. The solar cell module according to claim 2, wherein the insulating member has a substantially U-shaped cross section.

4. The solar cell module according to claim 1, wherein the insulating member comprises a polymer layer, a metal layer and an insulating layer, and wherein the metal layer is disposed between the insulating layer and the polymer layer.

5. The solar cell module according to claim 4, wherein the polymer layer comprises a fluorinated polymer or polyimide polymer.

6. The solar cell module according to claim 4, wherein the metal layer is an aluminum layer.

7. The solar cell module according to claim 4, wherein the insulating layer of the insulating member is made from polyethylene terephtalate (PET).

8. The solar cell module according to claim 4, wherein the insulating member further comprises an adhesive layer which adjoins the insulating layer and the side of the solar cell unit.

9. The solar cell module according to claim 1, wherein the first substrate has a thickness of about 3.2 mm to about 12 mm.

10. The solar cell module according to claim 8, wherein the second substrate has a thickness of about 3.2 mm to about 12 mm.

11. The solar cell module according to claim 1, wherein the photovoltaic member is formed directly on the first substrate.

12. The solar cell module according to claim 11, further comprises a sealing layer disposed between the first and second substrates and above the photovoltaic member.

13. The solar cell module according to claim 1, wherein the photovoltaic member comprises amorphous silicon.
